(19) United States
(12) Patent Application Publication
(10) Pub. No.: US 2014/0340660 A1
(43) Pub. Date: Nov. 20, 2014

(54) PATTERN FORMATION METHOD AND PATTERN FORMATION APPARATUS

(71) Applicant: KABUSHIKI KAISHA TOSHIBA, Tokyo (JP)

(72) Inventors: Masato SUZUKI, Kanagawa-ken (JP); Manabu Takakuwa, Mie-ken (JP); Kentaro Kasa, Kanagawa-ken (JP)

(21) Appl. No.: 13/972,398

(22) Filed: Aug. 21, 2013

(30) Foreign Application Priority Data
May 20, 2013 (JP) 2013-106546

(51) Int. Cl. G03F 7/20

(52) U.S. Cl. CPC G03F 7/20
USPC 355/53

(57) ABSTRACT

According to one embodiment, a pattern formation method includes preparing a mold including a first pattern, preparing a substrate including a second pattern, coating a photosensitive resin onto the substrate, bringing the mold into contact with the photosensitive resin, determining whether or not the photosensitive resin is filled between the first pattern and the second pattern, performing an alignment of the first pattern and the second pattern according to a first reference in the case where the photosensitive resin is filled between the first pattern and the second pattern, and performing the alignment of the first pattern and the second pattern according to a second reference different from the first reference in the case where the photosensitive resin is not filled between the first pattern and the second pattern, curing the photosensitive resin, and releasing the mold from the photosensitive resin.

### CROSS-REFERENCE TO RELATED APPLICATIONS

This application is based upon and claims the benefit of priority from Japanese Patent Application No. 2013-106546, filed on May 20, 2013; the entire contents of which are incorporated herein by reference.

### FIELD

Embodiments described herein relate generally to a pattern formation method and a pattern formation apparatus.

### BACKGROUND

Imprinting using a mold (a master) in which a concave-convex pattern is provided is drawing attention as one pattern formation method to form a fine pattern. When imprinting, a photosensitive resin is coated onto a substrate onto which the pattern is to be transferred; and the concave-convex pattern of the mold is brought into contact with the photosensitive resin. Then, the photosensitive resin is cured by irradiating light onto the photosensitive resin in a state in which an alignment of the mold and the substrate has been performed. Subsequently, the mold is released from the photosensitive resin. Thereby, the configuration of the concave-convex pattern of the mold is transferred onto the photosensitive resin. To increase the throughput in the pattern formation method, it is important to perform the alignment of the mold and the substrate in a short period of time.

### BRIEF DESCRIPTION OF THE DRAWINGS

FIG. 1 is a flowchart showing a pattern formation method according to a first embodiment;

FIG. 2A to FIG. 2D are schematic cross-sectional views showing a pattern formation method using a mold;

FIG. 3A and FIG. 3B are schematic views showing the mold;

FIG. 4 is a schematic plan view showing a substrate;

FIG. 5A to FIG. 6D are schematic views showing the alignment;

FIG. 7A to FIG. 8B are schematic views showing moiré and a waveform;

FIG. 9 is a schematic plan view showing a group of alignment patterns;

FIG. 10 is a schematic view showing the configuration of a pattern formation apparatus according to a second embodiment; and

FIG. 11 shows the hardware configuration of the computer.

### DETAILED DESCRIPTION

In general, according to one embodiment, a pattern formation method includes preparing a mold including a first pattern, preparing a substrate including a second pattern, coating a photosensitive resin onto the substrate, bringing the mold into contact with the photosensitive resin, determining whether or not the photosensitive resin is filled between the first pattern and the second pattern, performing an alignment of the first pattern and the second pattern according to a first reference in the case where the photosensitive resin is filled between the first pattern and the second pattern, and performing the alignment of the first pattern and the second pattern according to a second reference different from the first reference in the case where the photosensitive resin is not filled between the first pattern and the second pattern, curing the photosensitive resin, and releasing the mold from the photosensitive resin.

Various embodiments will be described hereinafter with reference to the accompanying the drawings. In the description hereinbelow, similar members are marked with like reference numerals, and a description is omitted as appropriate for members once described.

### First Embodiment

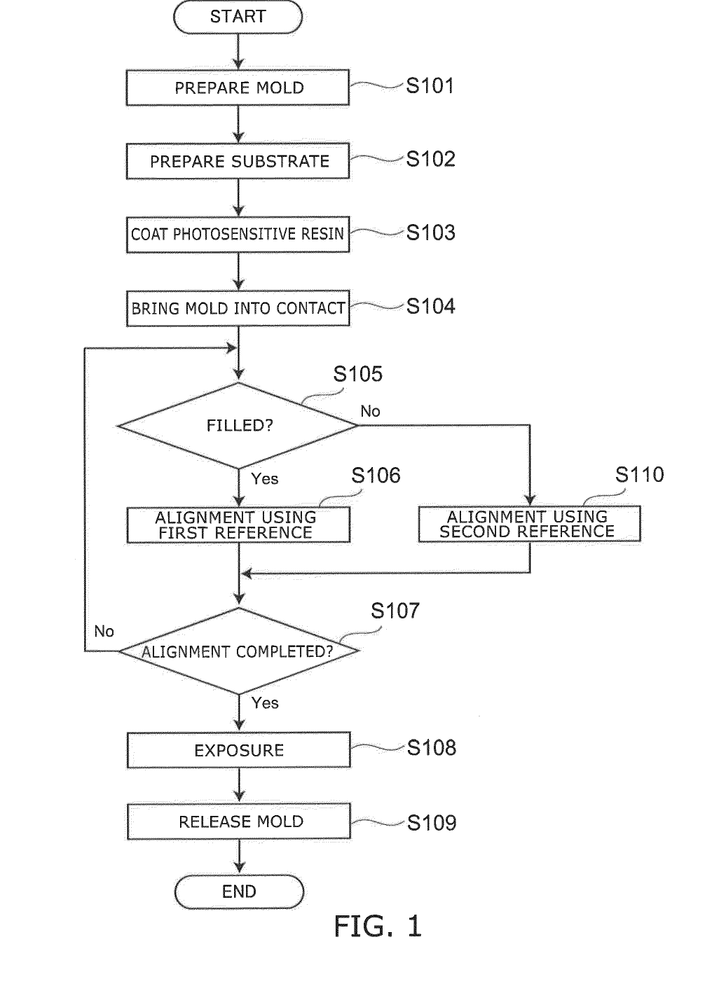

FIG. 1 is a flowchart showing a pattern formation method according to a first embodiment.

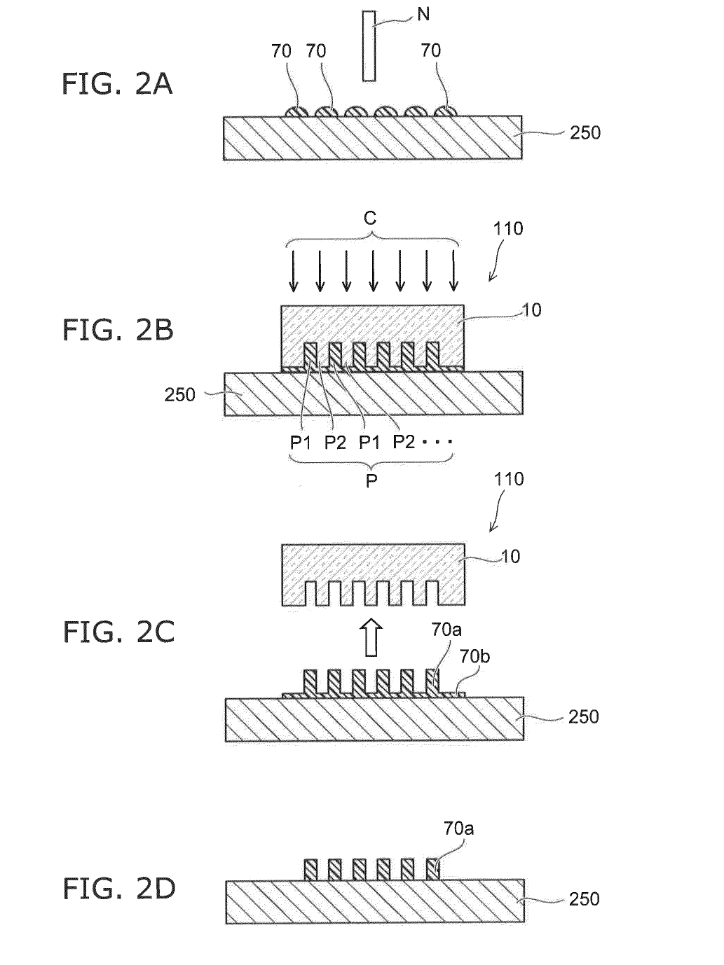

FIGS. 2A to 2D are schematic cross-sectional views showing a pattern formation method using a mold.

As shown in FIG. 1, the pattern formation method according to the first embodiment includes a process (step S101) of preparing a substrate, a process (step S102) of preparing a mold, a process (step S103) of coating a photosensitive resin, a process (step S104) of bringing the mold into contact, a process (step S105) of determining whether or not the photosensitive resin is filled, processes (steps S106 and S110) of performing an alignment using the first reference or the second reference, a process (step S107) of determining the alignment, a process (step S108) of performing an exposure, and a process (step S109) of releasing the mold.

The pattern formation method according to the embodiment is a pattern formation method by imprinting using a mold (a master) including a concave-convex pattern. In the pattern formation method according to the embodiment, the alignment of the mold and the substrate is performed without waiting for the completion of the filling of the photosensitive resin by switching the reference of the alignment of the mold and the substrate according to the state of the filling of the photosensitive resin. Thereby, the throughput of the pattern formation is increased by reducing the time that is necessary from the contact of the mold with the photosensitive resin to the completion of the alignment.

An example of a pattern formation method using a mold will now be described with reference to FIGS. 2A to 2D.

First, as shown in FIG. 2A, a photosensitive resin 70 is coated onto a substrate 250. The photosensitive resin 70 includes, for example, acrylic ester. The photosensitive resin 70 is coated onto the substrate 250 by, for example, inkjet from a nozzle N. The size of the liquid droplets of the photosensitive resin 70 is, for example, about several picoliters (pL). The spacing of the liquid droplets of the photosensitive resin 70 is, for example, not less than 10 micrometers (μm) and not more than 100 μm. The photosensitive resin 70 may be coated with a uniform thickness onto the substrate 250 by spin coating, etc.

Then, as shown in FIG. 2B, a mold 110 is prepared. The mold 110 includes a pattern portion P in which a concave-convex pattern is formed. Continuing, the pattern portion P of the mold 110 is brought into contact with the photosensitive resin 70. The photosensitive resin 70 enters the interior of a concave pattern P1 due to capillary action. The photosensitive resin 70 is filled into the concave pattern P1.

The pattern portion P of the mold 110 is brought into contact with the photosensitive resin 70; and the alignment of the mold 110 and the substrate 250 is performed.

Then, light C is irradiated from a base member 10 side of the mold 110 in the state in which the alignment of the mold 110 and the substrate 250 is complete. The light C is, for example, ultraviolet light. The light C is irradiated onto the photosensitive resin 70 by passing through the base member 10 and the pattern portion P. The photosensitive resin 70 is cured by being irradiated with the light C.

Continuing as shown in FIG. 2C, the mold 110 is released from the photosensitive resin 70. Thereby, a transfer pattern 70a, onto which the uneven configuration of the pattern portion P of the mold 110 is transferred, is formed on the substrate 250. When the mold 110 is brought into contact with the photosensitive resin 70, a slight gap is provided between the mold 110 and the substrate 250. The photosensitive resin 70 that enters the gap remains as a residual film 70b after the curing.

Then, processing is performed to remove the residual film 70b. For example, etch-back of the transfer pattern 70a and the residual film 70b is performed by RIE (Reactive Ion Etching). Thereby, as shown in FIG. 2D, only the transfer pattern 70a remains on the substrate 250.

A specific example of the pattern formation method according to the embodiment will now be described.

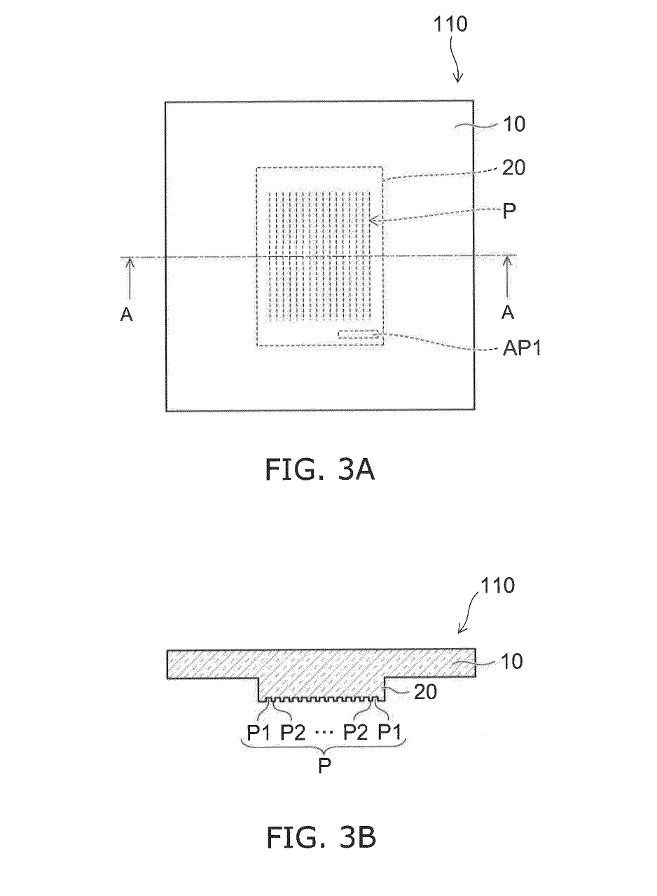

FIGS. 3A and 3B are schematic views showing the mold.

FIG. 3A is a schematic plan view of the mold 110. FIG. 3B is a schematic cross-sectional view of line A-A shown in FIG. 3A. The mold 110 shown in FIGS. 3A and 3B is an example of the mold that is prepared in step S101 of FIG. 1.

As shown in FIGS. 3A and 3B, the mold 110 includes the base member 10, a pedestal portion 20, and the pattern portion P. The base member 10 includes, for example, a material that is light-transmissive. The material of the base member 10 is, for example, silicon oxide (SiO₂) or quartz. The outline of the base member 10 is, for example, a rectangle. The size of the outline of the base member 10 is, for example, 150 millimeters (mm) long by 150 mm wide.

The pedestal portion 20 is provided to protrude from the central portion of the base member 10. The outline of the pedestal portion 20 is, for example, a rectangle. The size of the outline of the pedestal portion 20 is, for example, 33 mm long by 26 mm wide. The height of the pedestal portion 20 is, for example, 3 μm.

The pattern portion P includes the concave pattern P1 and a protrusion pattern P2 (a concave-convex pattern) provided in the pedestal portion 20. The concave pattern P1 is a pattern having a trench configuration that recedes from the surface of the pedestal portion 20. In the case where multiple concave patterns P1 are provided, the protrusion pattern P2 is between two mutually-adjacent concave patterns P1.

As shown in FIG. 3A, a first alignment pattern (a first pattern) AP1 is provided in the pedestal portion 20. The first alignment pattern AP1 is provided, for example, in the vicinity of the circumferential edge of the pedestal portion 20. The first alignment pattern AP1 may be provided inside the pattern portion P.

The first alignment pattern AP1 includes a concave-convex pattern having a prescribed configuration. The first alignment pattern AP1 is used to sense the positional shift between the mold 110 and the substrate 250 when overlaying the first alignment pattern AP1 onto an alignment pattern on the substrate side described below. As an example in the embodiment, the case is described where a line-and-space concave-convex pattern is included in the first alignment pattern AP1.

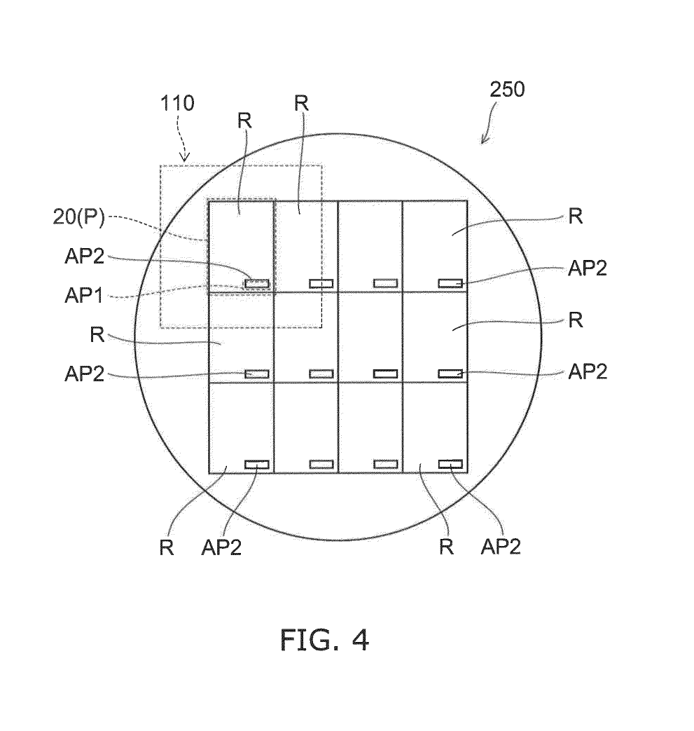

FIG. 4 is a schematic plan view showing a substrate.

The substrate 250 shown in FIG. 4 is, for example, a semiconductor wafer. The substrate 250 shown in FIG. 4 is an example of the substrate prepared in step S102 of FIG. 1. The substrate 250 may be any substrate such as an insulative substrate (a glass substrate, etc.), an SOI (Silicon On Insulator) substrate, etc. The substrate 250 includes a shot region R. The shot region R is the region where the pattern is transferred by one imprint by the mold 110. The shot region R is, for example, a region corresponding to one chip, a region corresponding to multiple chips, or a region corresponding to a portion inside one chip.

The substrate 250 includes the second alignment pattern (a second pattern) AP2. The second alignment pattern AP2 is provided inside the shot region R. In the case where multiple shot regions R are provided, the second alignment pattern AP2 is provided in each of the shot regions R.

The second alignment pattern AP2 includes a concave-convex pattern having a prescribed configuration. The second alignment pattern AP2 is used to sense the positional shift between the mold 110 and the substrate 250 when overlaying the second alignment pattern AP2 onto the first alignment pattern AP1 of the mold 110. As an example in the embodiment, the case is described where a line-and-space concave-convex pattern is included in the second alignment pattern AP2.

In the case where the pattern is formed by imprinting as shown in FIG. 4, the mold 110 is disposed on the shot region R of the substrate 250. Then, an alignment of the mold 110 and the substrate 250 is performed according to the overlap state between the first alignment pattern AP1 of the mold 110 and the second alignment pattern AP2 of the substrate 250.

For example, light (an alignment light) for the alignment is irradiated onto the first alignment pattern AP1 and the second alignment pattern AP2 in the state in which the mold 110 is disposed on the substrate 250. The alignment light includes light of a wavelength that does not cure the photosensitive resin 70.

The reflected light of the alignment light is received by a light receiving part (an alignment sensor); and the alignment is performed based on the waveform of the signal obtained by the light receiving part. For example, the alignment is performed using coherent light in the embodiment.

In the embodiment, the pitch in the first direction of the concave-convex pattern included in the first alignment pattern AP1 is different from the pitch in the first direction of the concave-convex pattern included in the second alignment pattern AP2. The first alignment pattern AP1 has a first spacing in a first direction. The second alignment pattern AP2 has a second spacing in the first direction. The second spacing is not an integer multiple of the first spacing and not the first spacing divided by an integer.

The first alignment pattern AP1 and the second alignment pattern AP2 have diffraction gratings. In other words, moiré (interference fringes) due to the reflected light (the diffracted light) of the alignment light occurs when the alignment light is irradiated in the state in which the first alignment pattern AP1 and the second alignment pattern AP2 overlap each other. The alignment is performed by sensing the shading of the moiré and determining the shift amount between the first alignment pattern AP1 and the second alignment pattern AP2 from the waveform based on the shading.

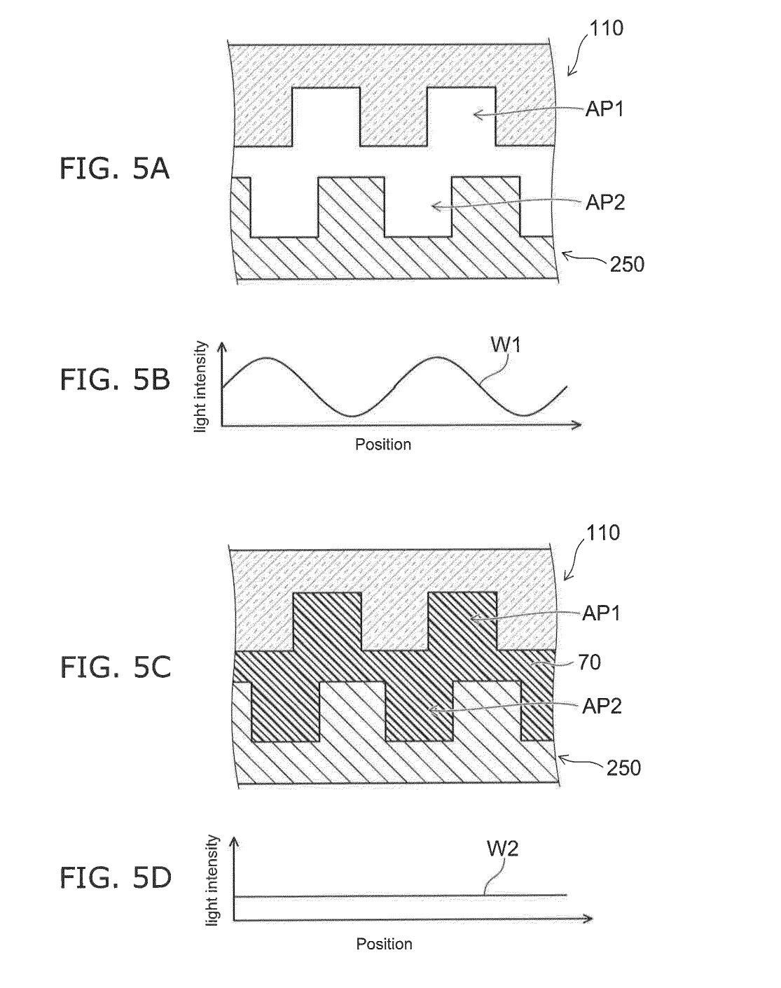

FIG. 5A to FIG. 6D are schematic views showing the alignment.

FIG. 5A shows the state in which the first alignment pattern AP1 and the second alignment pattern AP2 overlap each other, FIG. 5B shows a waveform W1 of the shading of the moiré occurring in the overlap state of FIG. 5A. In FIG. 5B, the horizontal axis is the position; and the vertical axis is the light intensity.

In the example shown in FIG. 5A, the photosensitive resin 70 is not filled between the first alignment pattern AP1 and the second alignment pattern AP2. In other words, air is interposed between the first alignment pattern AP1 and the second alignment pattern AP2.

To perform the alignment of the mold 110 and the substrate 250, for example, the positions of the peaks of the waveform W1 of the shading of the moiré such as that shown in FIG. 5B are sensed. The optical characteristics of the mold 110 are different from the optical characteristics of air. Accordingly, the waveform W1 has a large amplitude. Then, the positional relationship between the mold 110 and the substrate 250 is adjusted to cause the positions of the peaks that are sensed to be positioned at a prescribed position.

FIG. 5C shows the state in which the first alignment pattern AP1 and the second alignment pattern AP2 overlap each other. FIG. 5D shows a waveform W2 of the shading of the moiré occurring in the overlap state of FIG. 5C. In FIG. 5D, the horizontal axis is the position; and the vertical axis is the light intensity.

In the example shown in FIG. 5C, the photosensitive resin 70 is filled between the first alignment pattern AP1 and the second alignment pattern AP2. Here, in the case where the optical characteristics (e.g., the refractive index and the extinction coefficient at the wavelength of the alignment light) of the photosensitive resin 70 are substantially the same as the optical characteristics of the mold 110, the amplitude of the waveform W2 of the shading of the moiré becomes extremely small.

FIG. 6A shows the state in which the first alignment pattern AP1 and the second alignment pattern AP2 overlap each other. A light-shielding film SH, which is made of a material (e.g., chrome (Cr)) that has different optical characteristics than those of the mold 110 and the photosensitive resin 70, is provided in the concave pattern of the first alignment pattern AP1 of the mold 110 shown in FIG. 6A. FIG. 6B shows a waveform W10 of the shading of the moiré occurring in the overlap state of FIG. 6A. In FIG. 6B, the horizontal axis is the position; and the vertical axis is the light intensity.

In the example shown in FIG. 6A, the photosensitive resin 70 is not filled between the first alignment pattern AP1 and the second alignment pattern AP2. In other words, air is interposed between the first alignment pattern AP1 and the second alignment pattern AP2. Generally, the optical constants (e.g., the extinction coefficient and the refractive index) of air are different from the optical constants of the photosensitive resin 70 and the optical constants of the mold 110. Therefore, in the case where the mold 110 including the light-shielding film SH is used, the waveform W10 of the shading of the moiré has an amplitude that is substantially equivalent to that of the waveform W1 shown in FIG. 5B.

FIG. 6C shows the state in which the first alignment pattern AP1 and the second alignment pattern AP2 overlap each other. Similarly to the mold 110 shown in FIG. 6A, the mold 110 shown in FIG. 6C includes the light-shielding film SH. FIG. 6D shows a waveform W20 of the shading of the moiré occurring in the overlap state of FIG. 6C. In FIG. 6D, the horizontal axis is the position; and the vertical axis is the light intensity.

In the example shown in FIG. 6C, the photosensitive resin 70 is filled between the first alignment pattern AP1 and the second alignment pattern AP2. In the case where the light-shielding film SH is provided in the concave pattern of the first alignment pattern AP1 of the mold 110, the amplitude of the waveform W20 of the shading of the moiré is less than the amplitude of the waveform W10 shown in FIG. 6B. However, the amplitude of the waveform W20 is greater than the amplitude of the waveform W2 shown in FIG. 5D.

For example, even in the case where the optical characteristics of the photosensitive resin 70 are substantially the same as the optical characteristics of the mold 110, the amplitude of the waveform W20 is obtained when using the mold 110 including the light-shielding film SH.

In the pattern formation method according to the embodiment, to perform an alignment such as that recited above, a determination of whether or not the photosensitive resin 70 is filled between the first alignment pattern AP1 and the second alignment pattern AP2 is performed (step S105 of FIG. 1). Then, in the case where it is determined that the photosensitive resin 70 is filled between the first alignment pattern API and the second alignment pattern AP2, the alignment using the first reference is performed (step S106 of FIG. 1); and in the case where it is determined that the photosensitive resin 70 is not filled between the first alignment pattern AP1 and the second alignment pattern AP2, the alignment using the second reference which is different from the first reference is performed (step S110 of FIG. 1).

Here, the determination of whether or not the photosensitive resin 70 is filled between the first alignment pattern AP1 and the second alignment pattern AP2 is performed according to, for example, the change of the waveforms W1, W2, W10, and W20 such as those shown in FIG. 5B, FIG. 5D, FIG. 6B, and FIG. 6D.

For example, in the case where the light-shielding film SH is not provided in the mold 110 as shown in FIGS. 5A to 5D, the waveform W1 is obtained when the photosensitive resin 70 is not filled between the first alignment pattern AP1 and the second alignment pattern AP2; and the waveform W2 is obtained when the photosensitive resin 70 is filled. Accordingly, the information of whether or not the photosensitive resin 70 is filled is obtained from the waveforms (the waveform W1 and the waveform W2) of the signal of the reflected light of the alignment light obtained by the light receiving part.

Similarly, in the case where the light-shielding film SH is provided in the mold 110 as shown in FIGS. 6A to 6D, the information of whether or not the photosensitive resin 70 is filled is obtained from the waveforms (the waveform W10 and the waveform W20) of the signal obtained by the light receiving part.

Although the determination of whether or not the photosensitive resin 70 is filled is performed using the first alignment pattern AP1 and the second alignment pattern AP2 in the example recited above, another pattern may be used. For example, a third pattern (a pattern that is different from the first alignment pattern AP1 and the second alignment pattern AP2) may be provided in the mold 110; and the third pattern may be used to determine whether or not the photosensitive resin 70 is filled. Even in the case where the third pattern is used, it is sufficient to perform the determination according to the change of the waveform, intensity, phase, or the like of the reflected light of the alignment light that is caused by whether or not the photosensitive resin 70 is filled. It is desirable for the third pattern to be provided in the vicinity of the first alignment pattern AP1.

In the embodiment, the alignment of the mold 110 and the substrate 250 is performed using the first reference (step S106 of FIG. 1) in the case where it is determined that the photosensitive resin 70 is filled between the first alignment pattern AP1 and the second alignment pattern AP2 in step S105 shown in FIG. 1.

Here, the first reference includes a first range to sense the shading of the moiré in the case where the photosensitive resin 70 is filled between the first alignment pattern AP1 and the second alignment pattern AP2. For example, in the case where the photosensitive resin 70 is filled between the first alignment pattern AP1 and the second alignment pattern AP2 as shown in FIG. 6C, a first range RG1 having the amplitude of the waveform W20 shown in FIG. 6D is set as the detection range of the waveform W20.

On the other hand, the alignment of the mold 110 and the substrate 250 is performed using the second reference (step S110 of FIG. 1) in the case where it is determined that the photosensitive resin 70 is not filled between the first alignment pattern AP1 and the second alignment pattern AP2 in step S105 shown in FIG. 1.

The second reference includes a second range to sense the shading of the moiré in the case where the photosensitive resin 70 is not filled between the first alignment pattern AP1 and the second alignment pattern AP2. For example, in the case where the photosensitive resin 70 is not filled between the first alignment pattern AP1 and the second alignment pattern AP2 as shown in FIG. 6A, a second range RG2 having the amplitude of the waveform W10 shown in FIG. 6B is set as the detection range of the waveform W10. For example, the second range RG2 is wider than the first range RG1.

Thus, in the embodiment, the optimal detection range of the waveforms W10 and W20 when performing the alignment is set based on whether or not the photosensitive resin 70 is filled between the first alignment pattern AP1 and the second alignment pattern AP2. Accordingly, in the embodiment, the waveforms W10 and W20 are sensed using the optimal detection range in both the case where the photosensitive resin 70 is filled between the first alignment pattern API and the second alignment pattern AP2 and the case where the photosensitive resin 70 is not filled between the first alignment pattern AP1 and the second alignment pattern AP2.

Generally, in a pattern formation method by imprinting, the alignment of the mold 110 and the substrate 250 is performed after bringing the mold 110 into contact with the photosensitive resin 70 and waiting until the photosensitive resin 70 is filled between the first alignment pattern AP1 and the second alignment pattern AP2.

Conversely, in the embodiment, the alignment of the mold 110 and the substrate 250 is started after bringing the mold 110 into contact with the photosensitive resin 70 without waiting until the photosensitive resin 70 is filled between the first alignment pattern AP1 and the second alignment pattern AP2. In other words, in the embodiment, the alignment is started directly after bringing the mold 110 into contact with the photosensitive resin 70.

Also, the waveforms (e.g., the waveforms W20 and W10) are sensed using the optimal detection ranges (e.g., the first range RG1 and the second range RG2) based on the existence and absence, respectively, of the photosensitive resin 70 between the first alignment pattern AP1 and the second alignment pattern AP2. Accordingly, the wait time to fill the photosensitive resin 70 between the first alignment pattern API and the second alignment pattern AP2 after bringing the mold 110 into contact with the photosensitive resin 70 becomes unnecessary. That is, the throughput of the pattern formation increases.

Further, because the waveforms W10 and W20 are sensed using the optimal detection ranges based on the existence and absence, respectively, of the photosensitive resin 70 between the first alignment pattern AP1 and the second alignment pattern AP2 in the embodiment, the waveforms W10 and W20 are sensed with high precision regardless of the existence or absence of the photosensitive resin 70.

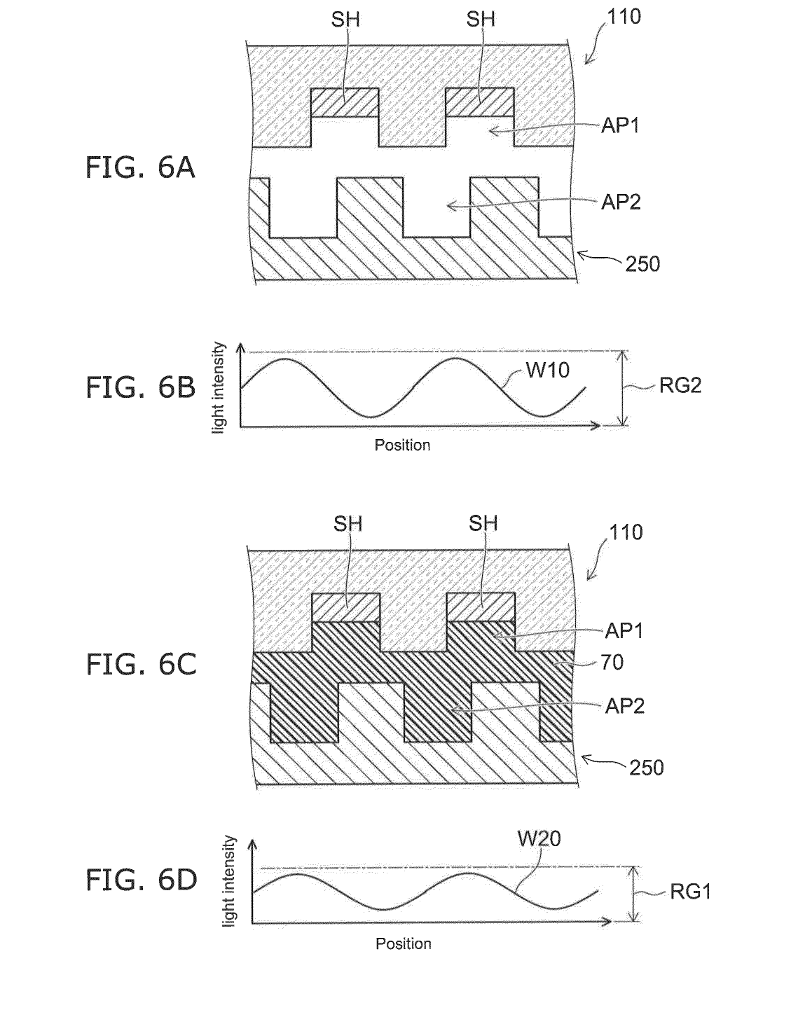

FIG. 7A to FIG. 8B are schematic views showing moiré and a waveform.

FIG. 7A shows moiré M1 in the state in which the photosensitive resin 70 is not filled. FIG. 7A shows the first alignment pattern AP1 and the second alignment pattern AP2. A portion of the first alignment pattern AP1 overlaps a portion of the second alignment pattern AP2. The moiré M1 occurs in the overlapping portion.

FIG. 7B shows a waveform W11 of the moiré M1. The waveform W11 has an amplitude AMP1. In such a case, the alignment is performed by sensing the waveform W11 using the second range RG2 included in the second reference as the detection range.

FIG. 8A shows moiré M2 in the state in which the photosensitive resin 70 is filled, FIG. 8A shows the first alignment pattern AP1 and the second alignment pattern AP2. A portion of the first alignment pattern API overlaps a portion of the second alignment pattern AP2. The moiré M2 occurs in the overlapping portion.

FIG. 8B shows a waveform W21 of the moiré M2. The waveform W21 has an amplitude AMP2. The amplitude AMP2 is less than the amplitude AMP1. In such a case, the alignment is performed by sensing the waveform W21 using the first range RG1 included in the first reference as the detection range.

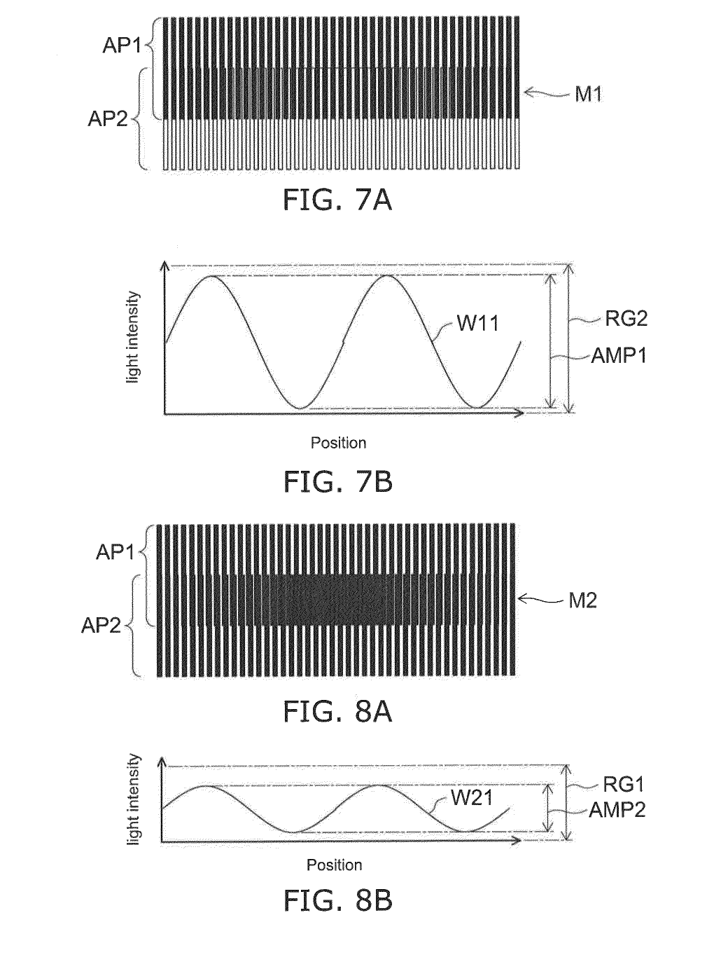

FIG. 9 is a schematic plan view showing a group of alignment patterns.

FIG. 9 shows an example of a group G of alignment patterns provided in the mold 110. Alignment patterns that correspond to the alignment patterns of the mold 110 are provided in the substrate 250.

As shown in FIG. 9, the group G of alignment patterns includes a pattern AP51 for performing a rough alignment and a pattern AP52 for performing a precise alignment. A plurality of the patterns AP51 and a plurality of the patterns AP52 may be provided. The pattern AP52 for performing the precise alignment includes, for example, the first alignment pattern AP1.

The pattern AP51 for performing the rough alignment may include a third pattern AP53 to determine whether or not the photosensitive resin 70 is filled.

After the alignment of the mold 110 and the substrate 250 is completed, the light from the light emitting part is irradiated onto the photosensitive resin 70. The photosensitive resin 70 is cured by the irradiation of the light. After the photosensitive resin 70 is cured, the mold 110 is released from the photosensitive resin 70. Thereby, a pattern, onto which the configuration of the concave-convex pattern of the mold 110 is transferred, is formed on the substrate 250.

In the pattern formation method according to the embodiment, the alignment is performed after bringing the mold 110 into contact with the photosensitive resin 70 without waiting until the photosensitive resin 70 is filled between the first alignment pattern AP1 and the second alignment pattern AP2. Accordingly, the throughput of the pattern formation increases. The alignment is performed for each of the shot regions R on the substrate 250. Accordingly, the effect of increasing the throughput is obtained more markedly as the number of shot regions R provided on the substrate 250 is increased.

### Second Embodiment

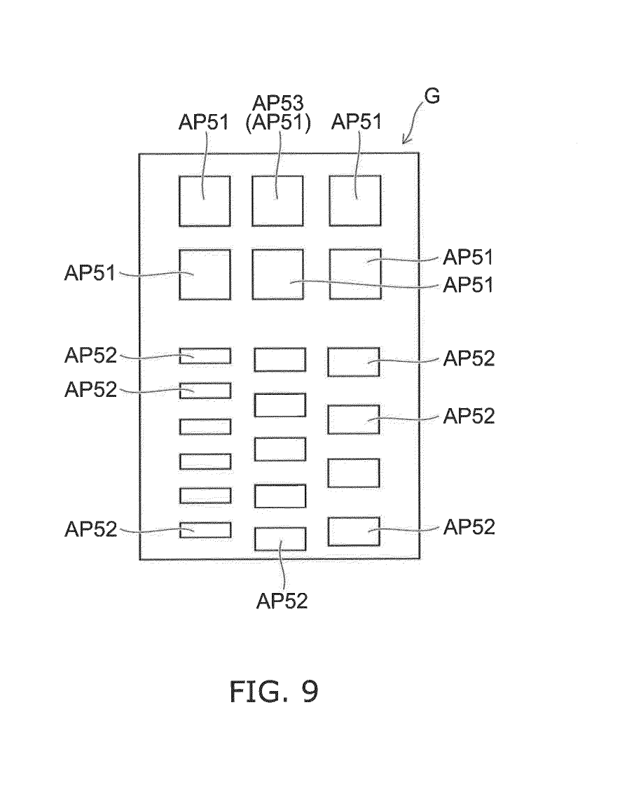

FIG. 10 is a schematic view showing the configuration of a pattern formation apparatus according to a second embodiment.

As shown in FIG. 10, the pattern formation apparatus 200 includes a mold holder (a first holder) 2, a substrate holder (a second holder) 5, a driver 8, a coating part 14, a light emitting part 12, and a controller 21. The pattern formation apparatus 200 further includes an alignment sensor 7, an alignment part 9, and a pressing part 15. The pattern formation apparatus 200 according to the embodiment is an imprint apparatus that transfers the configuration of the concave-convex pattern of the mold 110 onto the photosensitive resin 70 on the substrate 250.

The substrate 250 is, for example, a semiconductor substrate or a glass substrate. A foundation pattern is formed in the substrate 250. The substrate 250 may include a film formed on the foundation pattern. The film is at least one selected from an insulating film, a metal film (a conductive film), and a semiconductor film. A resin is coated onto the substrate 250 when transferring the pattern.

The substrate holder 5 is movably provided on a stage planar table 13. The substrate holder 5 is provided to be movable along two axes along an upper surface 13a of the stage planar table 13. Herein, the two axes along the upper surface 13a of the stage planar table 13 are taken as an X axis and a Y axis. The substrate holder 5 is provided to be movable also along a Z axis that is orthogonal to the X axis and the Y axis. It is desirable for the substrate holder 5 to be provided rotatably around the X axis, the Y axis, and the Z axis.

A reference mark table 6 is provided in the substrate holder 5. A reference mark (not shown) that is used as the reference position of the apparatus is mounted on the reference mark table 6. For example, the reference mark includes a diffraction grating. The reference mark is utilized to calibrate the alignment sensor 7 and align (control/adjust the orientation of) the mold 110. The reference mark is used as an origin on the substrate holder 5. The X, Y coordinates of the substrate 250 placed on the substrate holder 5 are coordinates having the reference mark table 6 as the origin.

The mold holder 2 fixes the mold 110. The mold holder 2 holds the circumferential edge portion of the mold 110 by, for example, vacuum-attaching. Here, the mold 110 is formed of a material such as quartz, fluorite, etc., that transmits ultraviolet (UV light). The concave-convex pattern formed in the mold 110 may include a pattern corresponding to the device pattern and alignment patterns used in the alignment of the mold 110 and the substrate 250. The mold holder 2 operates to align the mold 110 with the apparatus reference. The mold holder 2 is mounted to a base part 11.

The alignment part 9 and the pressing part 15 (the actuator) are mounted to the base part 11. The alignment part 9 includes an adjustment mechanism that finely adjusts the position (the orientation) of the mold 110. The relative positions of the mold 110 and the substrate 250 are corrected by the alignment part 9 finely adjusting the position (the orientation) of the mold 110. For example, the alignment part 9 performs the alignment of the substrate 250 and the mold 110 and the fine adjustment of the position of the mold 110 by receiving an instruction from the controller 21.

The pressing part 15 causes the mold 110 to distort by applying stress to the side surfaces of the mold 110. In the case of a rectangular mold 110, the pressing part 15 presses the mold 110 toward the center from the four side surfaces of the mold 110. Thereby, the alignment of the mold 110 is performed. Also, the pressing part 15 causes the mold 110 to deform by the balance of the pressing of the mold 110. For example, the pressing part 15 presses the mold 110 with a prescribed stress by receiving an instruction from the controller 21.

The alignment sensor 7 senses the first alignment pattern AP1 provided in the mold 110 and the second alignment pattern AP2 provided in the substrate 250. The alignment sensor 7 includes, for example, an optical camera. The relative positional shift amount of the first alignment pattern AP1 and the second alignment pattern AP2 is determined from, for example, the signal (the waveform) of the image of the moiré that is acquired by the optical camera.

The alignment sensor 7 senses the positional shift of the mold 110 with respect to the reference mark on the reference mark table 6 and the positional shift of the mold 110 using the substrate 250 as a reference. For example, the signal (the waveform) of the image of the moiré that is sensed by the alignment sensor 7 is transmitted to the controller 21. The alignment sensor 7 may be fixed or movable.

The controller 21 calculates the positional shift amount based on the positional information of the first alignment pattern AP1 and the second alignment pattern AP2 sensed by the alignment sensor 7. The alignment part 9 performs the alignment adjustment between the substrate 250 and the mold 110 according to the signal transmitted from the controller 21.

The controller 21 controls the light emitting part 12. When forming the pattern by imprinting, after coating the photosensitive resin 70 onto the substrate 250, light is irradiated onto the photosensitive resin 70 from the light emitting part 12 in the state of the concave-convex pattern of the mold 110 being in contact with the photosensitive resin 70. The controller 21 controls the irradiation timing and/or the irradiation amount of the light.

The light emitting part 12 emits, for example, ultraviolet light. For example, the light emitting part 12 is mounted directly above the mold 110. The position of the light emitting part 12 is not limited to being directly above the mold 110. In the case where the light emitting part 12 is disposed at a position other than directly above the mold 110, it is sufficient to use a configuration in which an optical path is set using an optical member such as a mirror, etc., and the light emitted from the light emitting part 12 is irradiated toward the mold 110 from directly above the mold 110.

The coating part 14 coats the photosensitive resin 70 onto the substrate 250. The coating part 14 includes a nozzle; and the photosensitive resin 70 is dropped onto the substrate 250 from the nozzle.

The driver 8 drives the mold holder 2 and the substrate holder 5. The driver 8 changes the relative positional relationship between the mold 110 and the substrate 250 by driving at least one selected from the mold holder 2 and the substrate holder 5.

After bringing the concave-convex pattern of the mold 110 into contact with the photosensitive resin 70, the controller 21 of the pattern formation apparatus 200 performs a control to perform the alignment of the mold 110 and the substrate 250 and irradiate light toward the photosensitive resin 70. The controller 21 executes the processing of step S101 to step S110 shown in FIG. 1. Here, the preparation of the mold shown in step S101 includes the mold 110 being held by the mold holder 2. The preparation of the substrate shown in step S102 includes the substrate 250 being held by the substrate holder 5.

According to such a pattern formation apparatus 200, the alignment is performed after bringing the mold 110 into contact with the photosensitive resin 70 without waiting until the photosensitive resin 70 is filled between the first alignment pattern AP1 and the second alignment pattern AP2. Accordingly, the throughput of the pattern formation increases.

### Third Embodiment

The pattern formation method according to the first embodiment described above is realizable as a program (a pattern formation program) that is executed by a computer.

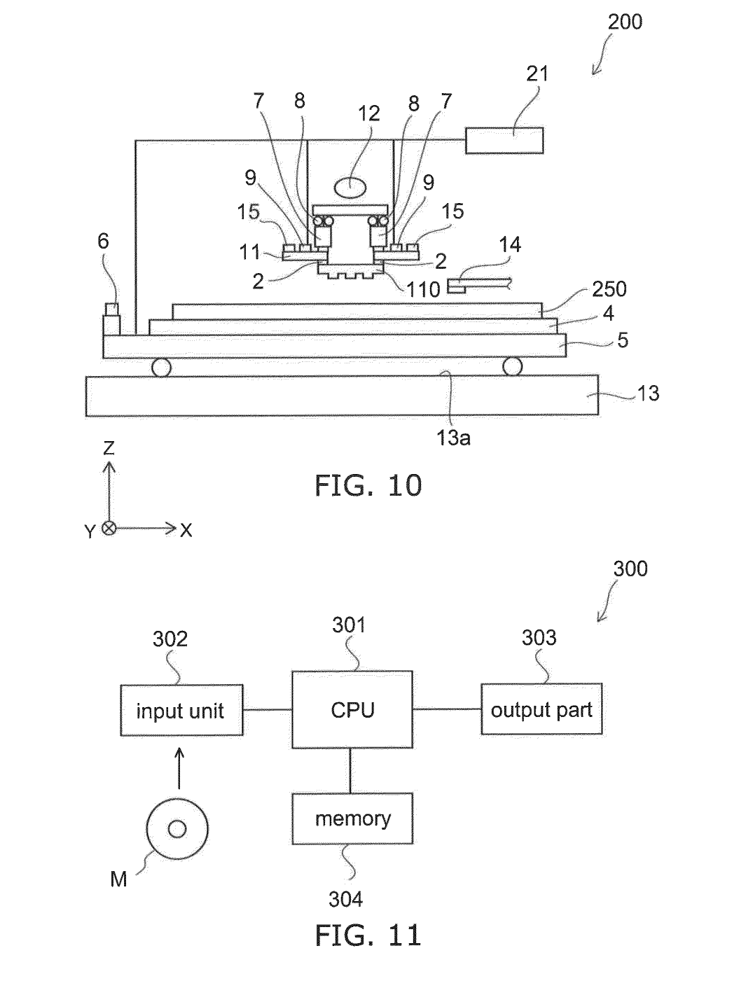

FIG. 11 shows the hardware configuration of the computer.

A computer 300 includes a central processing unit 301, an input unit 302, an output unit 303, and a memory 304. The input unit 302 also functions to read information recorded in a recording medium M. The pattern formation program is executed by the central processing unit 301.

The pattern formation program causes the computer 300 to execute the processing of step S101 to step S110 shown in FIG. 1.

### Fourth Embodiment

The pattern formation program may be recorded in a computer-readable recording medium. The recording medium M stores the processing of step S101 to step S110 shown in FIG. 1 in a format that is readable by the computer 300. The recording medium M may be a memory device such as a server, etc., connected to a network. Also, the pattern formation program may be distributed via the network.

As described above, according to the pattern formation method and the pattern formation apparatus according to the embodiments, the throughput of the pattern formation can be increased.

Although the embodiments are described above, the invention is not limited to these examples. For example, the alignment of the first alignment pattern AP1 and the second alignment pattern AP2 is not limited to sensing the shading of the moiré; and any means for sensing the information of the positional shift is applicable. Additions, deletions, or design modifications of components or appropriate combinations of the features of the embodiments appropriately made by one skilled in the art in regard to the embodiments described above are within the scope of the invention to the extent that the spirit of the invention is included.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A pattern formation method, comprising:
preparing a mold including a first pattern;
preparing a substrate including a second pattern;
coating a photosensitive resin onto the substrate;
bringing the mold into contact with the photosensitive resin;
determining whether or not the photosensitive resin is filled between the first pattern and the second pattern;
performing an alignment of the first pattern and the second pattern according to a first reference in the case where the photosensitive resin is filled between the first pattern and the second pattern, and performing the alignment of the first pattern and the second pattern according to a second reference different from the first reference in the case where the photosensitive resin is not filled between the first pattern and the second pattern;
curing the photosensitive resin; and
releasing the mold from the photosensitive resin.

2. The method according to claim 1, wherein
the first pattern has a first spacing in a first direction, and
the second pattern has a second spacing in the first direction, the second spacing being not an integer multiple of the first spacing and not the first spacing divided by an integer.

3. The method according to claim 1, wherein
the first pattern has a line-and-space pattern, and
the second pattern has a line-and-space pattern.

4. The method according to claim 1, wherein
the first pattern has a concave-convex pattern, and
the second pattern has a concave-convex pattern.

5. The method according to claim 1, wherein
the first pattern has a diffraction grating, and
the second pattern has a diffraction grating.

6. The method according to claim 1, wherein the determining of whether or not the photosensitive resin is filled includes determining whether or not the photosensitive resin is filled using information of reflected light of light irradiated between the first pattern and the second pattern.

7. The method according to claim 6, wherein an optical characteristic of the photosensitive resin is the same as an optical characteristic of the mold.

8. The method according to claim 1, wherein
the mold further includes a third pattern, and
the determining of whether or not the photosensitive resin is filled includes determining whether or not the photosensitive resin is filled between the third pattern and the substrate.

9. The method according to claim 8, wherein the determining of whether or not the photosensitive resin is filled includes determining whether or not the photosensitive resin is filled using information of reflected light of light irradiated between the third pattern and the substrate.

10. The method according to claim 1, wherein
the first reference includes a first range to sense information of a positional shift between the first pattern and the second pattern, and
the second reference includes a second range to sense the information of the positional shift, the second range being different from the first range.

11. A pattern formation apparatus, comprising:
a first holder configured to hold a mold including a first pattern;
a second holder configured to hold a substrate including a second pattern;
a driver configured to drive at least one selected from the first holder and the second holder;
a coating part configured to coat a photosensitive resin onto the substrate;
a light emitting part configured to irradiate light onto the photosensitive resin; and
a controller configured to control the coating part, the driver, and the light emitting part, the controller being configured to control:
the holding of the mold by the first holder;
placing the substrate on the second holder;
the coating of the photosensitive resin onto the substrate by the coating part;
the bringing of the mold into contact with the photosensitive resin by the driver;
determining whether or not the photosensitive resin is filled between the first pattern and the second pattern;
performing an alignment of the first pattern and the second pattern according to a first reference in the case where the photosensitive resin is filled between the first pattern and the second pattern, and performing the alignment of the first pattern and the second pattern according to a second reference different from the first reference in the case where the photosensitive resin is not filled between the first pattern and the second pattern;
curing the photosensitive resin by the irradiating of the light from the light emitting part; and
releasing the mold from the photosensitive resin.

12. The apparatus according to claim 11, wherein
the first pattern has a first spacing in a first direction;
the second pattern has a second spacing in the first direction, the second spacing being different from the first spacing; and
the second spacing is not an integer multiple of the first spacing and not the first spacing divided by an integer.

13. The apparatus according to claim 11, wherein
the first pattern has a diffraction grating, and
the second pattern has a diffraction grating.

14. The apparatus according to claim 11, wherein the controller is configured to determine whether or not the photosensitive resin is filled using information of reflected light of light irradiated between the first pattern and the second pattern.

15. The apparatus according to claim 11, wherein
the first reference is a first range to sense information of a positional shift between the first pattern and the second pattern, and
the second reference is a second range to sense the information of the positional shift, the second range being different from the first range.
